(19) United States
(12) Patent Application Publication
(10) Pub. No.: US 2021/0234475 A1
(43) Pub. Date: Jul. 29, 2021

(54) SCALABLE MULTI-LEVEL POWER CONVERTER

(71) Applicants: MAGNA INTERNATIONAL INC., Aurora (CA); UNIVERSITY OF WINDSOR, Windsor (CA)

(72) Inventors: Debmalya BANERJEE, Windsor (CA); Chunyan LAI, Montreal (CA); Jiangbo TIAN, Belle River (CA); Animesh KUNDU, Windsor (CA); Eshaan GHOSH, Windsor (CA); Narayan Chandra KAR, Tecumseh (CA); Jasmin Jijina SINKULAR, Bloomfield Hills, MI (US); Lakshmi Varaha IYER, Windsor (CA); Philip KORTA, Windsor (CA)

(21) Appl. No.: 15/734,830

(22) PCT Filed: Jun. 6, 2019
(86) PCT No.: PCT/US2019/035812

§ 371 Date: Dec. 3, 2020

Related U.S. Application Data
(60) Provisional application No. 62/681,244, filed on Jun. 6, 2018.

(51) Int. Cl. H02M 7/483; H02P 27/08

(52) U.S. Cl. CPC H02M 7/4835; H02P 27/08

(57) ABSTRACT

A multilevel power converter, or inverter, for converting a direct current electrical power to an alternating current electrical power includes one or more 2-level converters each including gallium nitride (GaN) transistors configured to switch two input lines to a three-phase output line. The multilevel power converter may be used in a motor drive circuit, which may provide a 3-phase AC supply. Two power converters, which may be 2-level or 3-level power converters, may be alternately switched to provide the AC power to an AC motor by an output stage including bi-directional switching transistors configured to switch a corresponding three-phase output lines from the multilevel power converters. The multilevel power converters switch input lines from a neutral-point clamped input stage including capacitors connected in series across input terminals having a DC voltage therebetween to energize a midpoint terminal with an intermediate voltage half of the voltage between the input terminals.

### CROSS-REFERENCE TO RELATED APPLICATIONS

This PCT International Patent Application claims the benefit of and priority to U.S. Provisional Patent Application Ser. No. 62/681,244 filed on Jun. 6, 2018, titled “Scalable Multi-Level Power Converter,” the entire disclosure of which is hereby incorporated by reference.

### FIELD

The present disclosure relates generally to multilevel power converters for converting direct current (DC) electrical power to alternating current (AC) electrical power. More specifically, the present disclosure relates to such multilevel power converters for use in motor drive circuits.

### BACKGROUND

This section provides background information related to the present disclosure which is not necessarily prior art.

Electric motor drives, also known as variable frequency drives (VFDs) are used in a variety of applications to provide alternating current (AC) electrical power to an electric motor. Electric motor drives are frequently used in electric vehicles for powering traction motors at a range of different speeds. Electric motor drives also have industrial and commercial applications such as for running blowers, conveyors, or other machines at a range of different speeds.

Such variable frequency drives commonly include multilevel voltage converters that use solid state switches to switch a DC source in order to generate an output having multiple different voltage levels. Historically, insulated gate bipolar transistors (IGBTs) or metal-oxide-semiconductor field-effect transistors (MOSFETs) are used as the switches. However, IGBTs and MOSFETs are limited in their operating speed and are not generally able to operate at more than 10 kHz to switch the high electrical currents required for motor drive applications.

Gallium Nitride (GaN) solid-state switches have the ability to rapidly switch the electrical currents required for motor drive applications. However, commercially available Gallium Nitride (GaN) solid-state switches are rated for operation at a maximum of 650V, less than the input DC voltage required for modern electric vehicles, which can have DC bus voltages of 800V or greater.

Thus, there is a need for multilevel power converters and motor drive circuits that overcome these shortcomings.

### SUMMARY

This section provides a general summary of the present disclosure and is not a comprehensive disclosure of its full scope or all of its features and advantages.

According to an aspect of the disclosure, a multilevel power converter for converting a direct current electrical power to an alternating current electrical power. The multilevel power converter includes a plurality of converter inputs for receiving a direct current voltage of the direct current electrical power. The multilevel power converter also includes a primary phase final output line for outputting a primary phase output of the alternating current electrical power, a secondary phase final output line for outputting a secondary phase output of the alternating current electrical power, and a tertiary phase final output line for outputting a tertiary phase output of the alternating current electrical power. In addition, the multilevel power converter includes a plurality of solid-state converter switches coupled to the plurality of converter inputs and to the primary phase final output line and the secondary phase final output line and the tertiary phase final output line. The plurality of solid-state converter switches are configured to switch the plurality of converter inputs to the primary phase final output line and the secondary phase final output line and the tertiary phase final output line.

According to another aspect, the multilevel power converter includes one or more 2-level converters, each including six Gallium Nitride (GaN) transistors or IGBTs configured to switch input DC lines to a three-phase output line.

In this way, a multilevel power converter, such as a 3-level converter may be constructed using 2-level converters as a unit building block. Use of 650V Gallium Nitride devices in the 2-level converter will produce a multilevel power converter capable to withstand an 800V DC input voltage.

According to yet another aspect of the disclosure, a motor drive circuit for an electric motor is also provided. The motor drive circuit includes a plurality of converter inputs for receiving a direct current voltage. The motor drive circuit also includes a first power converter including a plurality of solid-state converter switches. The plurality of solid-state converter switches of the first power converter are configured to switch a plurality of first input lines coupled to at least one of the plurality of converter inputs to a first primary phase output line and a first secondary phase output line and a first tertiary phase output line for three AC phases of the electric motor. The motor drive circuit additionally includes a second power converter including a plurality of solid-state converter switches. The plurality of solid-state converter switches of the second power converter are configured to switch a plurality of second input lines coupled to at least one of the plurality of converter inputs to a second primary phase output line and a second secondary phase output line and a second tertiary phase output line for the three AC phases of the electric motor. The motor drive circuit also includes an output stage including a plurality of bi-directional solid-state switches. The plurality of bi-directional solid-state switches of the output stage are configured to switch a corresponding one of the output lines from one of the first power converter and the second power converter to a primary phase final output line and a secondary phase final output line and a tertiary phase final output line to provide an AC power including the three AC phases to the electric motor.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic diagram of a motor drive including a conventional two-level inverter;

FIG. 2 illustrates an output voltage and current of the conventional two-level inverter of FIG. 1;

FIG. 3 is a circuit diagram of one phase leg of a prior art neutral point clamped multilevel power converter;

FIG. 4A is a schematic diagram of a 2-level converter using Galium Nitride (GaN) transistors according to aspects of the disclosure;

FIG. 4B is a schematic diagram of another 2-level converter using insulated-gate bipolar transistors (IGBTs) according to aspects of the disclosure;

FIG. 5A is a schematic diagram of a 3-level converter including two 2-level converters of the design shown in FIG. 4A according to aspects of the disclosure;

FIG. 5B is a schematic diagram of another 3-level converter including two 2-level converters of the design shown in FIG. 4B according to aspects of the disclosure;

FIG. 6A is a schematic diagram of a motor drive circuit including two 2-level converters according to aspects of the disclosure;

FIG. 6B is a schematic diagram of a bi-directional switch used in the motor drive circuit of FIG. 6A according to aspects of the disclosure;

FIG. 7A is a schematic diagram of a motor drive circuit including two 3-level converters according to aspects of the disclosure;

FIG. 7B is a schematic diagram of a bi-directional switch used in the motor drive circuit of FIG. 7A according to aspects of the disclosure;

FIG. 8 shows an additional motor drive circuit with metal oxide silicon controlled triodes for alternating current according to aspects of the disclosure;

FIG. 9 shows example pulse width modulation waveforms of a primary phase operation of a primary phase high insulated gate bipolar transistor and a primary phase low insulated gate bipolar transistor of a first power converter and the primary phase high triode for alternating current of the motor drive circuit of FIG. 8 according to aspects of the disclosure;

FIG. 10 shows a pulse width modulation logic generation structure for a primary phase of the motor drive circuit of FIG. 8 according to aspects of the disclosure;

FIGS. 11 and 12 show waveforms of positive and negative carrier signals with the corresponding reference voltage waveforms used by the pulse width modulation logic generation structure of FIG. 10 according to aspects of the disclosure;

FIG. 13 shows voltage and current waveforms for a 400V input voltage to the motor drive circuit of FIG. 8 according to aspects of the disclosure;

FIG. 14 shows an example line to line voltage of the motor drive circuit shown in FIG. 8 according to aspects of the disclosure;

FIG. 15 shows three phase current waveforms output by the motor drive circuit of FIG. 8 and Fast Fourier Transform (FFT) results of the three phase output according to aspects of the disclosure;

FIG. 16 illustrates the calculation of power for two converters of the motor drive circuit of FIG. 8 according to aspects of the disclosure; and

FIG. 17 shows another motor drive circuit with metal oxide silicon controlled triodes for alternating current.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to a multilevel power converter and motor drive circuit of the type well-suited for use in many applications. The multilevel power converter and motor drive circuit of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

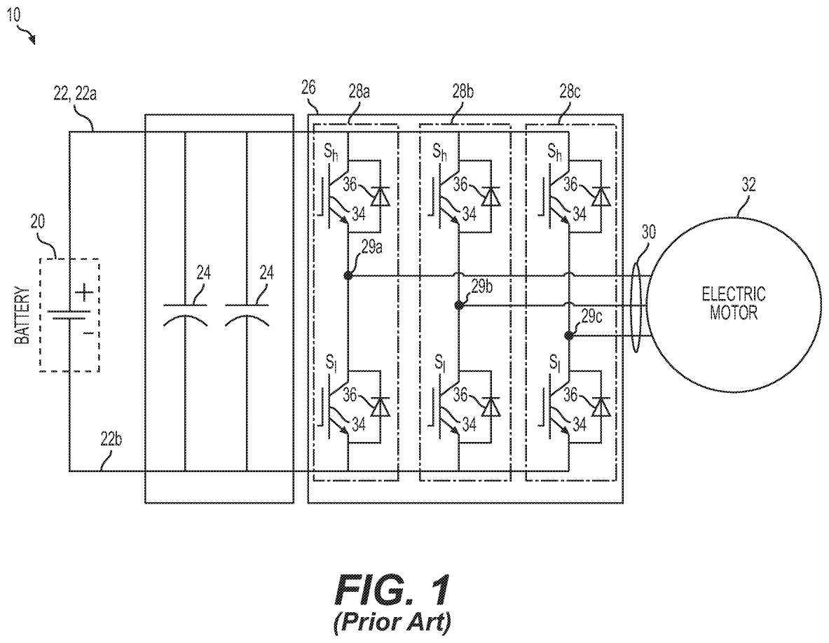

FIG. 1 illustrates a motor drive 10, having a conventional two-level inverter. The motor drive 10 includes a battery as a direct current (DC) source 20 to supply a DC electrical power upon a DC link bus 22 including a high-side conductor 22a and a low-side conductor 22b , with the high-side conductor 22a having a higher voltage potential than the low-side conductor 22b . A set of two smoothing capacitors 24 are connected across the DC link bus 22 between the high-side conductor 22a and the low-side conductor 22b to maintain the DC voltage thereacross. The first motor drive 10 also includes a first inverter 26 having three phase drivers 28a , 28b , 28c , with each of the phase drivers 28a , 28b , 28c configured to switch current from the DC link bus 22 to supply AC power upon a corresponding output terminal 29a , 29b , 29c . The output terminals 29a , 29b , 29c are connected to corresponding ones of three output terminals 30, which deliver the alternating current (AC) power as three-phase AC power to an electric motor 32.

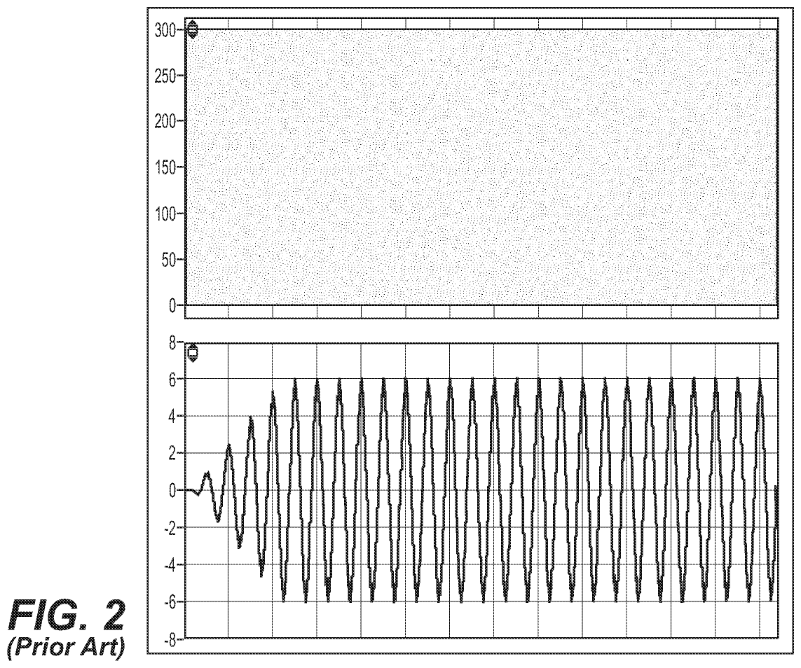

Each of the phase drivers 28 within the first inverter 26 of the first motor drive 10 includes a high-side solid-state switch Sₕ configured to selectively conduct current between a corresponding one of the output terminals 29a , 29b , 29c and the high-side conductor 22a of the DC link bus 22. Each of the phase drivers 28 also includes a low-side solid-state switch Sₗ configured to selectively conduct current between a corresponding one of the output terminals 29a , 29b , 29c and the low-side conductor 22b of the DC link bus 22. Each of the solid-state switches Sₕ, Sₗ includes a switching transistor 34 and a body diode 36. FIG. 2 shows the output voltage and current of a conventional two-level inverter, such as the motor drive 10 shown in FIG. 1.

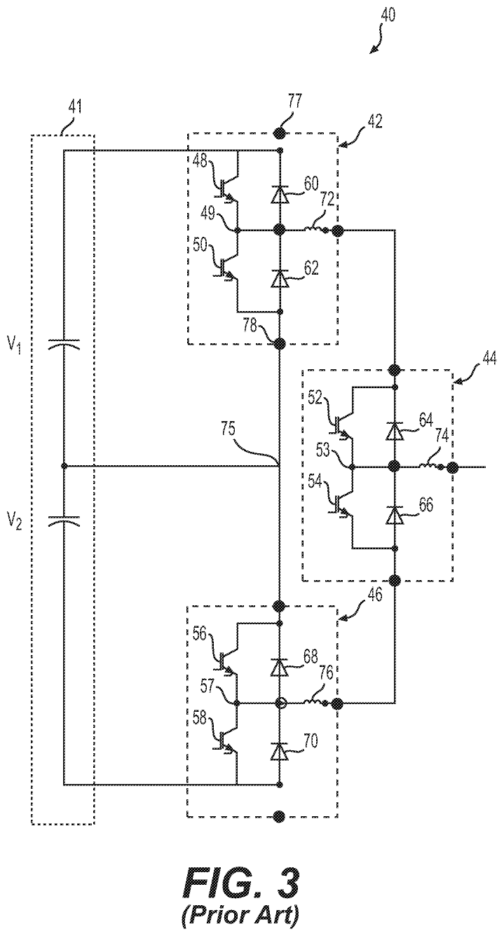

While motor drives can utilize two-level inverters as discussed above, some applications also utilize three level converters. As disclosed in U.S. Pat. No. 8,228,695 and reproduced in FIG. 3, a circuit diagram of one leg of a neutral point clamped (NPC) three level converter 40 is provided and utilizes insulated-gate bipolar transistor (IGBT) modules coupled to a DC link 41 to provide input voltages V1 and V2. The converter 40 includes three dual IGBT modules 42, 44, 46 for each leg of the NPC three level converter 40. If the converter 40 is a three-phase converter, nine dual IGBT modules are used. Each of the dual IGBT modules 42, 44, 46 comprises two IGBTs (IGBTs 48, 50 for top IGBT module, 52, 54 for middle IGBT module and 56, 58 for bottom IGBT module). The two IGBTs of each of the IGBT modules are connected in series and provide a first mid-point 49, a second mid-point 53, and a third point 57. IGBTs modules include anti-parallel diodes connected across the midpoints (shown as 60, 62, 64, 66, 68, 70).

With these conventional or known multilevel power converter designs in mind, an objective of the present disclosure is to provide a high-performance Gallium Nitride (GaN)/Silicon Carbide (SiC) based power converter with benefits in performance of thermal design of the converter. GaN or SiC based devices may provide lower converter losses compared to devices used in the prior art such that it may be implemented with simplified cooling that does not require cumbersome and costly liquid cooled converter systems.

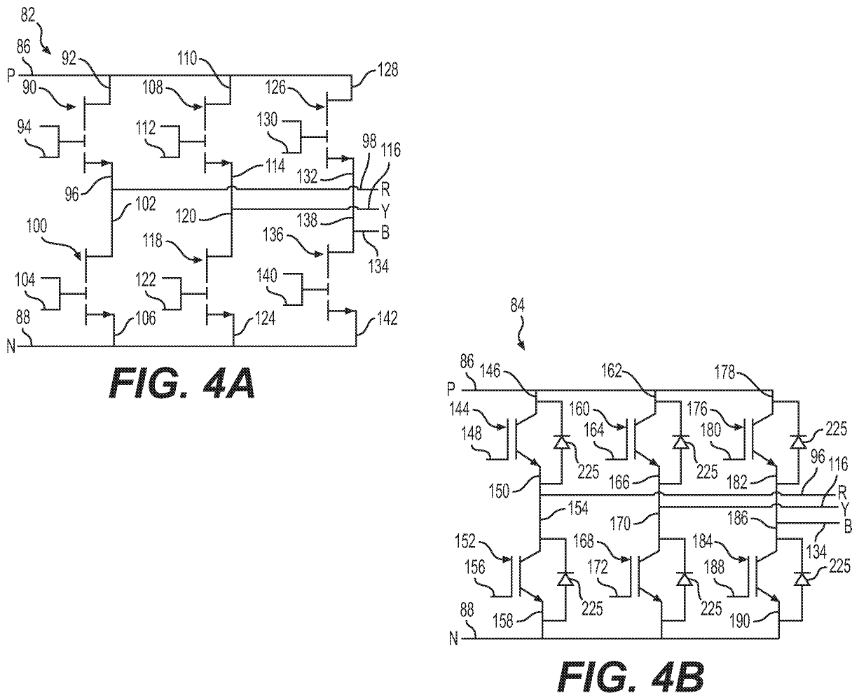

Referring initially to FIGS. 4A-7B, example embodiments of multilevel power converters 80, 280, 380, 480, 580, 680 are shown for converting a direct current electrical power to an alternating current electrical power, with recurring features marked with identical reference numerals. The multilevel power converter 80, 280, 380, 480, 580, 680 may also be called a multilevel or multi-level inverter.

The multilevel power converters 80, 280, 380, 480, 580, 680 described herein include two or more 2-level converters 82, 84. An example embodiment of such a 2-level converter 82 is shown in FIG. 4A. Each of the 2-level converters 82 include a positive direct current input line 86 and a negative direct current input line 88 and a plurality of solid-state converter switches 90, 100, 108, 118, 126, 136. Specifically, the plurality of solid-state converter switches are each configured to switch the positive direct current input line 86 and the negative direct current input line 88 to a three-phase output 98, 116, 134. The plurality of solid-state converter switches 90, 100, 108, 118, 126, 136 include six gallium nitride (GaN) transistors 90, 100, 108, 118, 126, 136.

As shown, each 2-level converter 82 includes a primary phase high gallium nitride transistor 90 including a primary phase high drain 92 connected to the positive direct current input line 86 and a primary phase high gate 94 and a primary phase high source 96 connected to a primary phase output line 98. Each 2-level converter 82 also includes a primary phase low gallium nitride transistor 100 including a primary phase low drain 102 connected to the primary phase high source 96 and the primary phase output line 98 and a primary phase low gate 104 and a primary phase low source 106 connected to the negative direct current input line 88.

The 2-level converter 82 additionally includes a secondary phase high gallium nitride transistor 108 including a secondary phase high drain 110 connected to the positive direct current input line 84 and a secondary phase high gate 112 and a secondary phase high source 114 connected to a secondary phase output line 116. In addition, the 2-level converter 82 includes a secondary phase low gallium nitride transistor 118 including a secondary phase low drain 120 connected to the secondary phase high source 114 and the secondary phase output line 116 and a secondary phase low gate 122 and a secondary phase low source 124 connected to the negative direct current input line 88.

The 2-level converter 82 additionally includes a tertiary phase high gallium nitride transistor 126 including a tertiary phase high drain 128 connected to the positive direct current input line 84 and a tertiary phase high gate 130 and a tertiary phase high source 132 connected to a tertiary phase output line 134. Each 2-level converter 82 also includes a tertiary phase low gallium nitride transistor 136 including a tertiary phase low drain 138 connected to the tertiary phase high source 132 and the tertiary phase output line 134 and a tertiary phase low gate 140 and a tertiary phase low source 142 connected to the negative direct current input line 88. Each of the gallium nitride (GaN) transistors 90, 100, 108, 118, 126, 136 is operated by a control signal which may be provided by a controller and which may be, for example a pulse-width modulation (PWM) signal, discussed in more detail below.

Another example of such a 2-level converter 84 is shown in FIG. 4B. Again, the positive direct current input line 86 and the negative direct current input line 88 are provided along with the plurality of solid-state converter switches 144, 152, 160, 168, 176, 184. In more detail, the plurality of solid-state converter switches 144, 152, 160, 168, 176, 184 can include six insulated gate bipolar transistors (IGBTs) 144, 152, 160, 168, 176, 184. So, each 2-level converter 84 includes a primary phase high insulated gate bipolar transistor 144 including a primary phase high collector 146 connected to the positive direct current input line 84 and a primary phase high base 148 and a primary phase high emitter 150 connected to the primary phase output line 98. The 2-level converter 84 also includes a primary phase low insulated gate bipolar transistor 152 including a primary phase low collector 154 connected to the primary phase high emitter 150 and the primary phase output line 98 and a primary phase low base 156 and a primary phase low emitter 158 connected to the negative direct current input line 88.

In addition, the 2-level converter 84 includes a secondary phase high insulated gate bipolar transistor 160 including a secondary phase high collector 162 connected to the positive direct current input line 86 and a secondary phase high base 164 and a secondary phase high emitter 166 connected to the secondary phase output line 116. Each 2-level converter 84 also includes a secondary phase low insulated gate bipolar transistor 168 including a secondary phase low collector 170 connected to the secondary phase high emitter 166 and the secondary phase output line 116 and a secondary phase low base 172 and a secondary phase low emitter 174 connected to the negative direct current input line 88.

The 2-level converter 84 additionally includes a tertiary phase high insulated gate bipolar transistor 176 including a tertiary phase high collector 178 connected to the positive direct current input line 86 and a tertiary phase high base 180 and a tertiary phase high emitter 182 connected to the tertiary phase output line 134. The 2-level converter 84 also includes a tertiary phase low insulated gate bipolar transistor 184 including a tertiary phase low collector 186 connected to the tertiary phase high emitter 182 and the tertiary phase output line 134 and a tertiary phase low base 188 and a tertiary phase low emitter 190 connected to the negative direct current input line 88. Each of the IGBTs 144, 152, 160, 168, 176, 184 is operated by a control signal which may be provided by a controller and which may be, for example a pulse-width modulation (PWM) signal. More specifically, the 2-level converters 82, 84 disclosed herein are voltage source inverters (VSIs), since the DC voltage supplied at the positive direct current input line 84 and the negative direct current input line 86 remains constant.

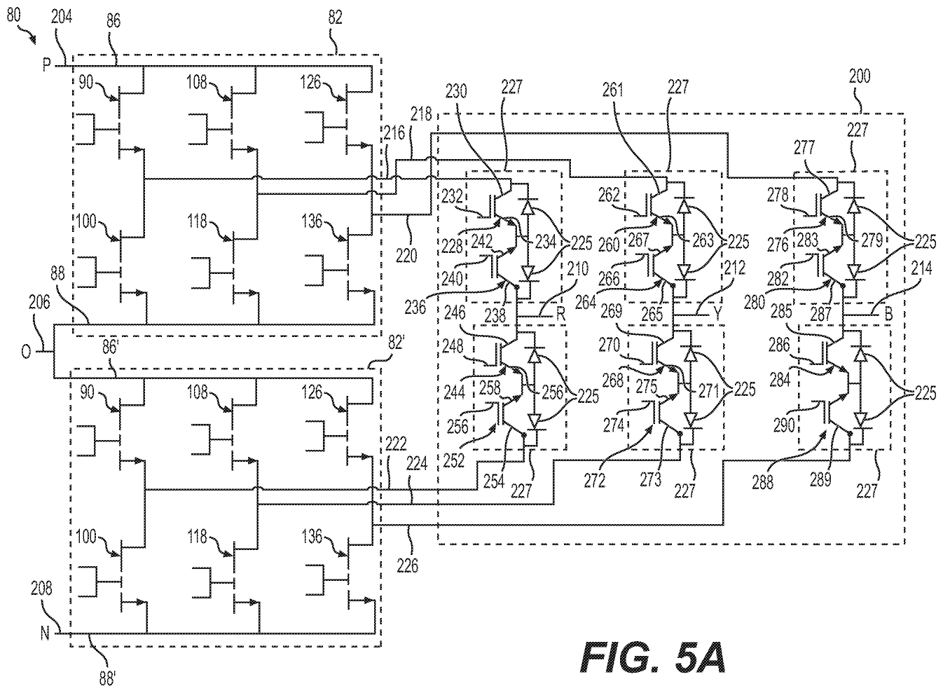

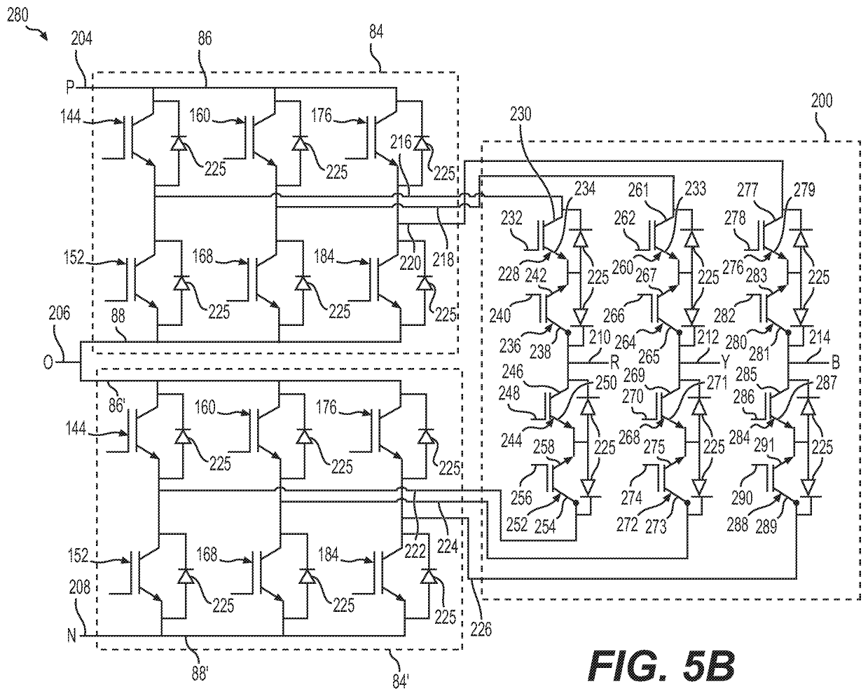

As shown in FIGS. 5A and 5B, exemplary embodiments of multilevel power converters 80, 280 each include a plurality of the 2-level converters 82, 84 discussed above. More specifically, the multilevel power converters 80, 280 shown in FIGS. 5A and 5B include two of the 2-level converters 82, 82′, 84, 84′ connected through a 3-level output stage 200 to function as a 3-level converter. The multilevel power converter 80, 280 include a plurality of converter inputs 204, 206, 208 for receiving a direct current voltage of the direct current electrical power. Because the multilevel power converters 80, 280 shown in FIG. 5A and 5B are 3-level converters, the plurality of converter inputs includes a 3-level positive direct current input line 204 and a 3-level intermediate direct current input line 206 and a 3-level negative direct current input line 208. The multilevel power converters 80, 280 each also include a 3-level primary phase final output line 210 for outputting a primary phase output of the alternating current electrical power and a 3-level secondary phase final output line 212 for outputting a secondary phase output of the alternating current electrical power and a 3-level tertiary phase final output line 214 for outputting a tertiary phase output of the alternating current electrical power. So, the multilevel power converters 80, 280 include a plurality of solid-state converter switches (GaN transistors 90, 100, 108, 118, 126, 136 as part of two 2-level converters 82, 82′) or a plurality of solid-state converter switches (IGBTs 144, 152, 160, 168, 176, 184 as part of two 2-level converters 84, 84′) coupled to the plurality of converter inputs 204, 206, 208 and to the primary phase final output line 210 and the secondary phase final output line 212 and the tertiary phase final output line 214 through the 3-level output stage 200. Thus, the multilevel power converters 80, 280 are configured to switch the plurality of converter inputs 204, 206, 208 to the primary phase final output line 210 and the secondary phase final output line 212 and the tertiary phase final output line 214.

The plurality of 2-level converters 82, 82′, 84, 84′ include a first 2-level converter 82, 84 (first power converter) and a second 2-level converter 82′, 84′ (second power converter). The 2-level converters 82, 82′ shown in FIG. 5A utilize GaN transistors (as in FIG. 4A), while the 2-level converters shown 84, 84′ in FIG. 5B are IGBTs (as in FIG. 4B). As discussed, the first 2-level converter 82, 84 is configured to switch the 3-level positive direct current input line 204 (a first positive direct current input line 86 of the first 2-level converter 82, 84) and the 3-level intermediate direct current input line 206 (a first negative direct current input line 88 of the first 2-level converter 82, 84) to a first primary phase output line 216 and a first secondary phase output line 218 and a first tertiary phase output line 220. The second 2-level converter 82′, 84′ is configured to switch the 3-level intermediate direct current input line 206 (a second positive direct current input line 86′ of the second 2-level converter 82′, 84′) and the 3-level negative direct current input line 208 (a second negative direct current input line 88′ of the second 2-level converter 82′, 84′) to a second primary phase output line 222 and a second secondary phase output line 224 and a second tertiary phase output line 226.

As mentioned above, the 3-level converters or multilevel power converters 80, 280 also include a 3-level output stage 200 including a plurality of bi-directional solid-state switches 227 configured to switch a corresponding one of the output lines 216, 218, 220, 222, 224, 226 from one of the first 2-level power converter 82, 84 and the second 2-level power converter 82′, 84′ to the 3-level primary phase final output line 210 and the 3-level secondary phase final output line 212 and the 3-level tertiary phase final output line 214.

As shown in FIGS. 4A and 5A, the GaN transistor-based 2-level converters 82, 82′ do not include anti-parallel diodes 225 for any of the gallium nitride (GaN) transistors 90, 100, 108, 118, 126, 136. Instead, they have reverse conducting capability through the source-to-drain channel. As shown in FIGS. 4B and 5B, each of the IGBT-based 2-level converters 84, 84′ include an anti-parallel diode 225 connected in parallel across switched output terminals of each of the IGBTs 144, 152, 160, 168, 176, 184.

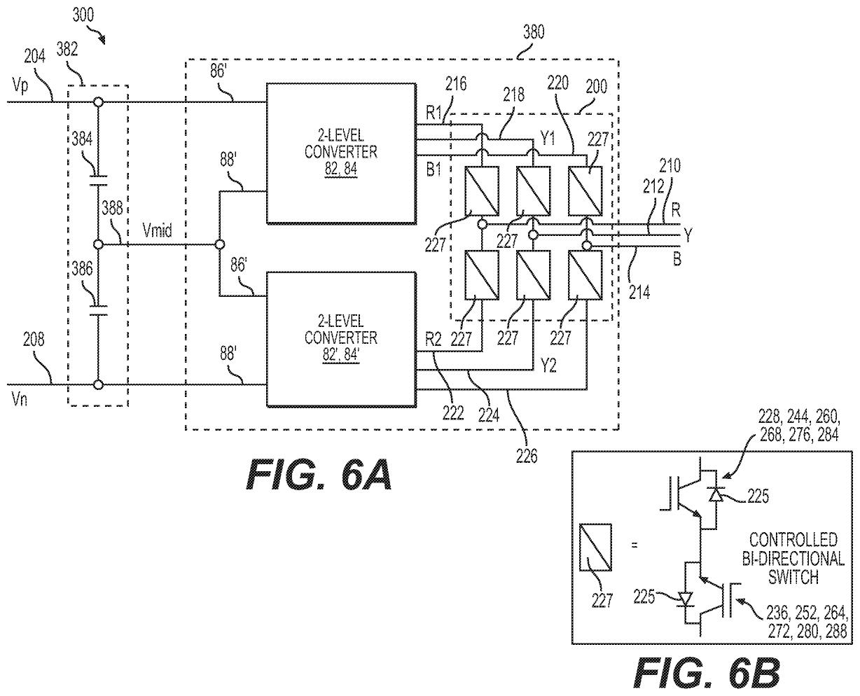

As shown in FIG. 6A, a motor drive circuit 300 including a scalable 3-level converter 380 for an electric motor (e.g., electric motor 32 of FIG. 1) is provided. Similar to the 3-level converters or multilevel power converters 80, 280 discussed above and shown in FIGS. 5A and 5B, the motor drive circuit 300 includes a plurality of converter inputs 204, 208 for receiving a direct current voltage (e.g., a 3-level positive direct current input line 204 and a 3-level negative direct current input line 208). The motor drive circuit 300 includes a first power converter 82, 84 that includes a plurality of solid-state converter switches (e.g., configured as the 2-level converter 82, 84 shown in FIGS. 4A and 4B) that are configured to switch the plurality of first input lines 86, 88 coupled to at least one of the plurality of converter inputs 204, 208 to a first primary phase output line 216 and a first secondary phase output line 218 and a first tertiary phase output line 220 for three AC phases of the electric motor 32. The motor drive circuit 300 also includes a second power converter 82′, 84′ (another 2-level converter) that includes a plurality of solid-state converter switches that are configured to switch the plurality of second input lines 86′, 88′ coupled to at least one of the plurality of converter inputs 204, 208 to a second primary phase output line 222 and a second secondary phase output line 224 and a second tertiary phase output line 226 for the three AC phases of the electric motor 32.

The motor drive circuit 300 additionally includes the 3-level output stage 200. As mentioned, the 3-level output stage 200 includes a plurality of bi-directional solid-state switches 227, discussed in further detail below, that are configured to switch a corresponding one of the output lines 216, 218, 220, 222, 224, 226 from one of the first power converter 82, 84 and the second power converter 82′, 84′ to a primary phase final output line 210 and a secondary phase final output line 212 and a tertiary phase final output line 214 to provide an AC power including the three AC phases to the electric motor 32. Although the example motor drive circuit 300 is configured for 3-phase operation, it should be appreciated that a similar motor drive circuit may be constructed for single phase operation. By appropriately switching using bi-directional switches 227, the motor drive circuit 300 can be used for multi-phase and open end winding motor drive.

The motor drive circuit 300 also includes a neutral-point clamped input stage 382 coupled to the first power converter 82, 84 and the second power converter 82′, 84′. The neutral-point clamped input stage 382 includes a first input capacitor 384 and a second input capacitor 386 connected in series across the 3-level positive direct current input line 204 and the 3-level negative direct current input line 208. The 3-level positive direct current input line 204 and the 3-level negative direct current input line 208 have a DC voltage (Vp−Vn) therebetween. A midpoint terminal 388 is disposed between the first input capacitor 384 and a second input capacitor 386 and is energized to half of the DC voltage. Other configurations or arrangements may be provided for the input stage 382 such as, for example, an active device having one or more switches or a battery having one or more first battery cells connected between the midpoint terminal 388 and 3-level positive direct current input line 204 and one or more second battery cells connected between the midpoint terminal 388 and 3-level negative direct current input line 208.

The 2-level converters 82, 82′, 84, 84′ shown in FIG. 6A consist of reduced leakage inductance bus bar systems. The connection between the bi-directional switches 227 to the load terminals, or three-phase output lines 210, 212, 214 of the multilevel power converter 380 have higher leakage inductance, which is not a problem as far as the functionality of the multilevel power converter 380 is concerned.

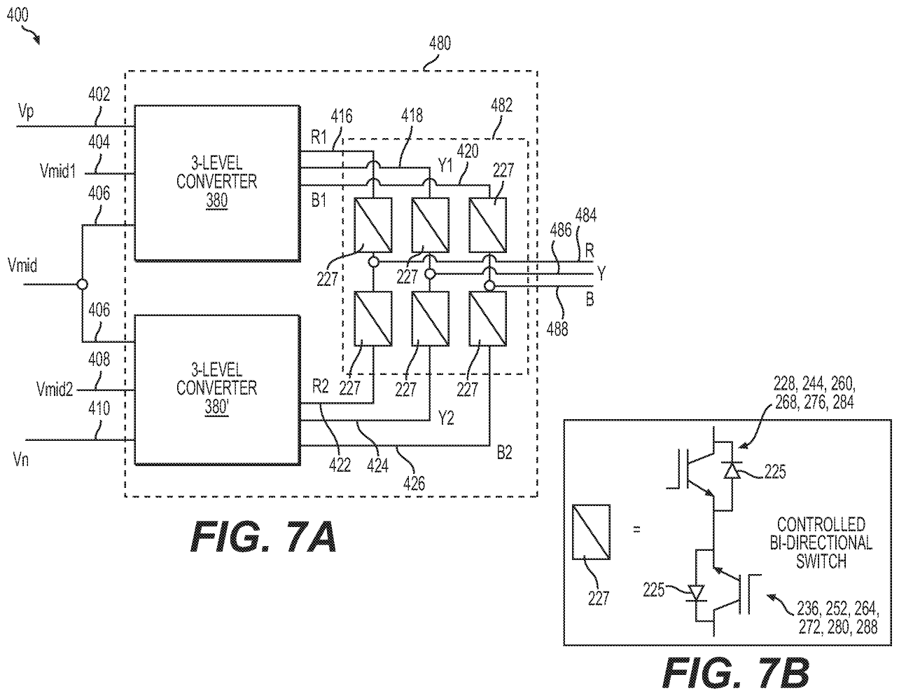

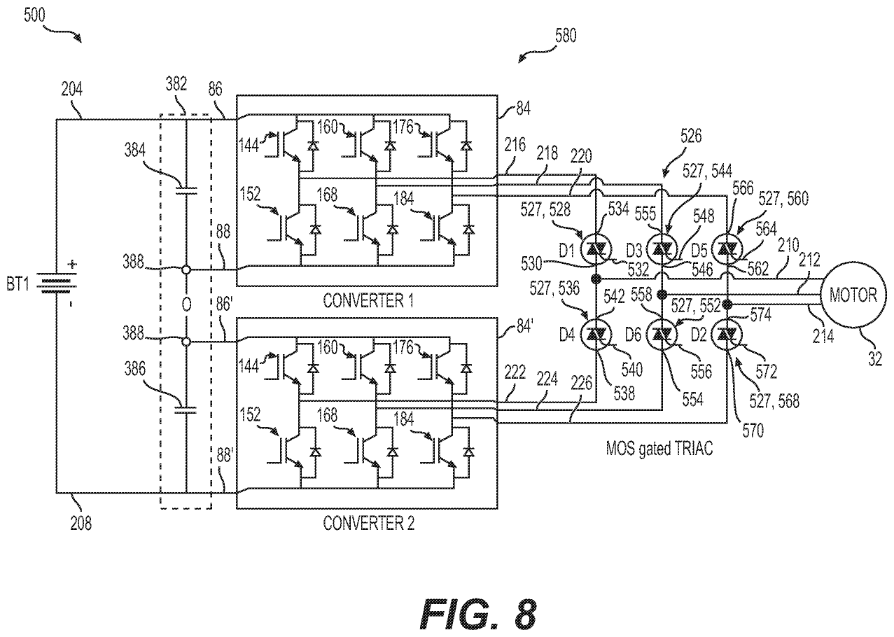

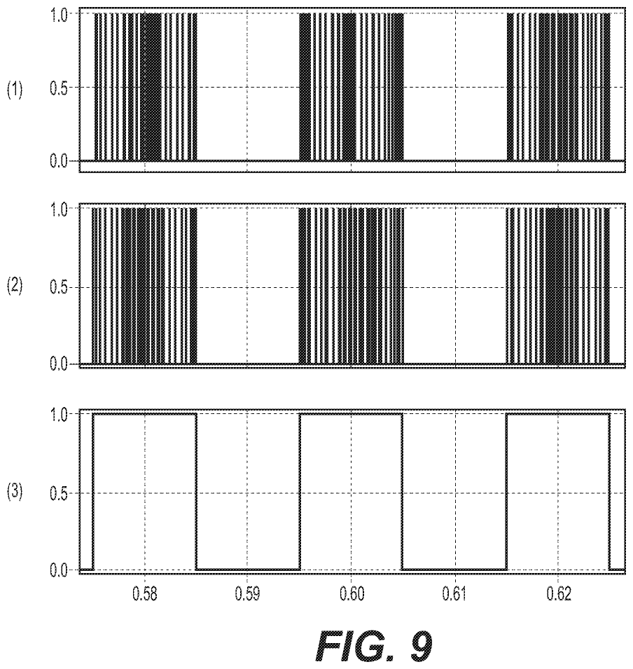

As shown in the example of FIG. 7A, another motor drive circuit 400 includes a scalable 5-level converter 480. The scalable 5-level converter 480 is constructed from two 3-level converters 380, 380′, each configured to switch three DC input lines 204, 204′, 206, 206′, 208, 208′ ultimately coupled to a three-phase final output line 484, 486, 488. Specifically, the plurality of converter inputs of the scalable 5-level converter 480 includes a 5-level positive direct current input line 402 and a 5-level first intermediate direct current input line 404 and a 5-level second intermediate direct current input line 406 and a 5-level third intermediate direct current input line 408 and a 5-level negative direct current input line 410. Each of the first power converter 380 and the second power converter 380′ is a 3-level converter 380, 380′. Each of the 3-level converters 380, 380′ may be similar to the 3-level converter 380 shown in FIG. 6A and each comprises a 3-level positive direct current input line 204, 204′ coupled to one of the 5-level positive direct current input line 402 and the 5-level second intermediate direct current input line 406. A 3-level intermediate direct current input line 206, 206′ of each of the 3-level converters 380, 380′ is coupled to one of the 5-level first intermediate direct current input line 404 and the 5-level third direct current input line 408. A 3-level negative direct current input line 208, 208′ of each of the 3-level converters 380, 380′ is coupled to one of the 5-level second intermediate direct current input line 406 and the 5-level negative direct current input line 410.

As discussed above, each of the 3-level converters 380, 380′ also includes a first 2-level converter 82, 84 configured to switch a first positive direct current input line 86 coupled to the 3-level positive direct current input line 204, 204′ and a first negative direct current input line 88 coupled to the 3-level intermediate direct current input line 206, 206′ and to a first primary phase output line 416 and a first secondary phase output line 418 and a first tertiary phase output line 420. In addition, each of the 3-level converters 380, 380′ includes a second 2-level converter 82′, 84′ configured to switch a second positive direct current input line 86′ coupled to the 3-level intermediate direct current input line 206, 206′ and a second negative direct current input line 88′ coupled to the 3-level negative direct current input line 208, 208′ and to a second primary phase output line 422 and the second secondary phase output line 424 and the second tertiary phase output line 426. Each 3-level converter 380, 380′ also includes a 3-level output stage 200 including a plurality of 3-level bi-directional solid-state switches 227 configured to switch a corresponding one of the output lines 216, 218, 220, 222, 224, 226 from one of the first 2-level power converter 82, 84 and the second 2-level power converter 82′, 84′ to a 3-level primary phase output line 210 and a 3-level secondary phase output line 212 and a 3-level secondary phase output line 214 (each being one of the output lines 416, 418, 420, 422, 424, 426). Again, each of the plurality of solid-state converter switches (used in the 2-level converters 82, 82′, 84, 84′) can, for example, be a gallium nitride (GaN) transistor or an insulated gate bipolar transistor.

The motor drive circuit 400 additionally includes a 5-level output stage 482. The 5-level output stage 482 is identical to the 3-level output stage 200 described above and includes a plurality of bi-directional solid-state switches 227, discussed in further detail below, that are configured to switch a corresponding one of the output lines 416, 416′, 418, 418′, 420, 420′ from one of the first power converter 380 and the second power converter 380′ to a 5-level primary phase final output line 484 and a 5-level secondary phase final output line 486 and a 5-level tertiary phase final output line 488 to provide an AC power including the three AC phases to the electric motor 32.

Although not shown in FIG. 7A, one or more input stages may generate the different voltages provided to the various different DC input lines 402, 404, 406, 408, 410. While the example motor drive circuit 400 is configured for 3-phase operation, it should be appreciated that a similar motor drive circuit may be constructed for single phase operation. By appropriately switching using bi-directional switches 227, the system can be used for multi-phase and open end winding motor drive.

As detailed in FIGS. 5A, 5B, 6B, and 7B, the plurality of bi-directional switches 227 of the 3-level output stage 200 of the multilevel power converter 80, 280, 380 and the 5-level output stage 482 of the multilevel power converter 480 each include two IGBTs to switch one phase of a three-phase output from one of the power converters 82, 82′, 84, 84′, 380, 380′ to the final output lines 210, 212, 214, 484, 486, 488 to provide an AC power to the electric motor 32. According to an aspect, and as illustrated in FIG. 6A, the output stage 200 includes six bidirectional switches 227 (Insulated Gate Bipolar Transistor (IGBT) modules) switching at fundamental frequency and connected by simple wire connection, not with a bus bar connection.

More specifically, for the primary phase, the plurality of bi-directional solid-state switches 227 includes a first primary phase upper insulated gate bipolar transistor 228 including a first primary phase upper drain 230 coupled to the first primary phase output line 216, 416 of the first power converter 82, 84, 380 and a first primary phase upper gate 232 and first primary phase upper source 234. The plurality of bi-directional solid-state switches 227 also includes a second primary phase upper insulated gate bipolar transistor 236 including a second primary phase upper drain 238 coupled to the primary phase final output line 210, 484 and a second primary phase upper gate 240 and second primary phase upper source 242 coupled to the first primary phase upper source 234. In addition, the plurality of bi-directional solid-state switches includes a first primary phase lower insulated gate bipolar transistor 244 including a first primary phase lower drain 246 coupled to the primary phase final output line 210, 484 and a first primary phase lower gate 248 and first primary phase lower source 250. The plurality of bi-directional solid-state switches 227 includes a second primary phase lower insulated gate bipolar transistor 252 including a second primary phase lower drain 254 coupled to the second primary phase output line 222, 422 of the second power converter 82′, 84′, 380′ and a second primary phase lower gate 256 and a second primary phase lower source 258 coupled to the first primary phase lower source 250.

For the secondary phase, the plurality of bi-directional solid-state switches 227 includes a first secondary phase upper insulated gate bipolar transistor 260 including a first secondary phase upper drain 261 coupled to the first secondary phase output line 218, 418 of the first power converter 82, 84, 380 and a first secondary phase upper gate 262 and a first secondary phase upper source 263. The plurality of bi-directional solid-state switches 227 includes a second secondary phase upper insulated gate bipolar transistor 264 including a second secondary phase upper drain 265 coupled to the secondary phase final output line 212, 486 and a second secondary phase upper gate 266 and a second secondary phase upper source 267 coupled to the first secondary phase upper source 263. Also, the plurality of bi-directional solid-state switches 227 includes a first secondary phase lower insulated gate bipolar transistor 268 including a first secondary phase lower drain 269 coupled to the secondary phase final output line 212, 486 and a first secondary phase lower gate 270 and a first secondary phase lower source 271. The plurality of bi-directional solid-state switches 227 additionally includes a second secondary phase lower insulated gate bipolar transistor 272 including a second secondary phase lower drain 273 coupled to the second secondary phase output line 222, 422 of the second power converter 82′, 84′, 380′ and a second secondary phase lower gate 274 and second secondary phase lower source 275 coupled to the first secondary phase lower source 271.

For the tertiary phase, the plurality of bi-directional solid-state switches 227 includes a first tertiary phase upper insulated gate bipolar transistor 276 including a first tertiary phase upper drain 277 coupled to the first tertiary phase output line 220, 420 of the first power converter 82, 84, 380 and a first tertiary phase upper gate 278 and first tertiary phase upper source 279. The plurality of bi-directional solid-state switches 227 also includes a second tertiary phase upper insulated gate bipolar transistor 280 including a second tertiary phase upper drain 281 coupled to the tertiary phase final output line 214, 488 and a second tertiary phase upper gate 282 and second tertiary phase upper source 283 coupled to the first tertiary phase upper source 279. In addition, the plurality of bi-directional solid-state switches 227 includes a first tertiary phase lower insulated gate bipolar transistor 284 including a first tertiary phase lower drain 285 coupled to the tertiary phase final output line 214, 488 and a first tertiary phase lower gate 286 and first tertiary phase lower source 287. The plurality of bi-directional solid-state switches 227 also includes a second tertiary phase lower insulated gate bipolar transistor 288 including a second tertiary phase lower drain 289 coupled to the second tertiary phase output line 226, 426 of the second power converter 82,′ 84′, 380′ and a second tertiary phase lower gate 290 and second tertiary phase lower source 291 coupled to the first tertiary phase lower source 287. Each of the bi-directional switches 227 includes a pair of anti-parallel diodes 225 connected in parallel across switched output terminals of each of the IGBTs 228, 236, 244, 252, 260, 264, 268, 272, 276, 280, 284, 288. Nevertheless, the IGBT modules used as bi-directional switches 227 need not be short circuit protected. They can be operated in the case of motor side line-line or phase to ground faults.

According to another aspect, another motor drive circuit 500 including a scalable multilevel power converter 580 is provided in FIG. 8. The motor drive circuit 500 includes a first power converter 84 and a second power converter 84′ (e.g., using IGBTs 144, 152, 160, 168, 176, 184 as in FIG. 4B) and a neutral-point clamped input stage 382 coupled to the first power converter 84 and the second power converter 84′ similar to that utilized in the motor drive circuit 300 shown in FIG. 6A. The motor drive circuit 500 includes a plurality of converter inputs 204, 208 for receiving a direct current voltage (e.g., a 3-level positive direct current input line 204 and a 3-level negative direct current input line 208). The first power converter 84 includes a plurality of solid-state converter switches 144, 152, 160, 168, 176, 184 (configured as the 2-level converter 84 shown in FIG. 4B) that are configured to switch a plurality of first input lines 86, 88 coupled to at least one of the plurality of converter inputs 204, 208 to a first primary phase output line 216 and a first secondary phase output line 218 and a first tertiary phase output line 220 for three AC phases of the electric motor 32. The motor drive circuit 500 also includes a second power converter 84′ (another 2-level converter) that includes a plurality of solid-state converter switches 144, 152, 160, 168, 176, 184 that are configured to switch the plurality of second input lines 86′, 88′ coupled to at least one of the plurality of converter inputs 204, 208 to a second primary phase output line 222 and a second secondary phase output line 224 and a second tertiary phase output line 226 for the three AC phases of the electric motor 32. Again, each of the two 2-level converters 84, 84′ includes six IGBTs, 144, 152, 160, 168, 176, 184 and may be the type shown in FIG. 4B.

However, the motor drive circuit 500 includes a triode output stage 526 that does not include IGBTs. Instead each of the plurality of bi-directional solid-state switches 527 is a metal oxide silicon controlled triode for alternating current (TRIAC) or MOS gated TRIAC, for example, MOS gate controlled TRIACs may be formed from two IXYS MOS gated thryristors arranged back-to-back. Otherwise, if simple TRIACs are used, a very small rating static compensator (STATCOM) (voltage source inverters, for reactive current control) can be used in the shunt path of the motor drive. MOS gated TRIAC functionally matches with anti-parallelly connected gate turn-off thyristors (GTOs), or symmetrical gate commutated thyristors (SGCTs) with a common gate connection. This provides scalability of current of the motor drive circuit 500.

In more detail, for the primary phase, the plurality of bi-directional solid-state switches 527 includes a primary phase high triode for alternating current 528 including a primary phase high triode first anode 530 coupled to the primary phase final output line 210 and a primary phase high triode gate 532 and a primary phase high triode second anode 534 coupled to the first primary phase output line 216 of the first power converter 84. The plurality of bi-directional solid-state switches 527 also includes a primary phase low triode for alternating current 536 including a primary phase low triode first anode 538 coupled to the second primary phase output line 222 of the second power converter 84′ and a primary phase low triode gate 540 and a primary phase low triode second anode 542 coupled to the primary phase high triode first anode 530 and the primary phase final output line 210.

In addition, for the secondary phase, the plurality of bi-directional solid-state switches 527 includes a secondary phase high triode for alternating current 544 including a secondary phase high triode first anode 546 coupled to the secondary phase final output line 212 and a secondary phase high triode gate 548 and a secondary phase high triode second anode 550 coupled to the first secondary phase output line 218 of the first power converter 84. The plurality of bi-directional solid-state switches 527 additionally includes a secondary phase low triode for alternating current 552 including a secondary phase low triode first anode 554 coupled to the second secondary phase output line 224 of the second power converter 84′ and a secondary phase low triode gate 556 and a secondary phase low triode second anode 558 coupled to the secondary phase high triode first anode 546 and the secondary phase final output line 212.

For the tertiary phase, the plurality of bi-directional solid-state switches 527 includes a tertiary phase high triode for alternating current 560 including a tertiary phase high triode first anode 562 coupled to the tertiary phase final output line 214 and a tertiary phase high triode gate 564 and a tertiary phase high triode second anode 566 coupled to the first tertiary phase output line 220 of the first power converter 84. The plurality of bi-directional solid-state switches 527 additionally includes a tertiary phase low triode for alternating current 568 including a tertiary phase low triode first anode 570 coupled to the second tertiary phase output line 226 of the second power converter 84′ and a tertiary phase low triode gate 572 and a tertiary phase low triode second anode 574 coupled to the tertiary phase high triode first anode 562 and the tertiary phase final output line 214.

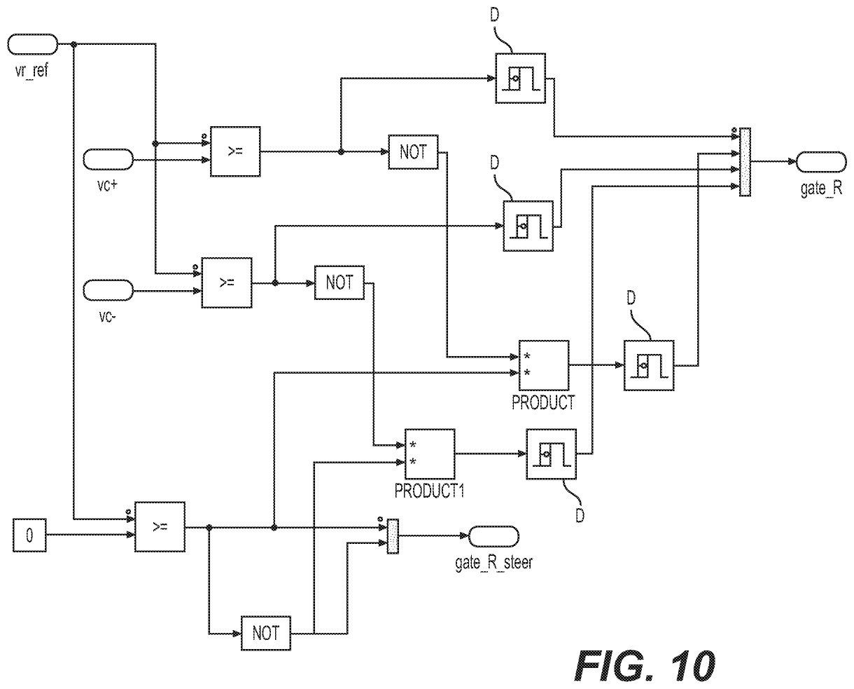

FIGS. 9(1)-9(3) shows example pulse width modulation (PWM) waveforms of the primary phase (R-phase) top switches (the primary phase high insulated gate bipolar transistor 144 and primary phase low insulated gate bipolar transistor 152 of the first power converter 84) and the primary phase high triode for alternating current 528 of FIG. 8. Specifically, FIG. 9(1) shows the PWM waveform to control the primary phase high insulated gate bipolar transistor 144 of the first power converter 84 and FIG. 9(2) shows the PWM waveform to control the primary phase low insulated gate bipolar transistor 152 of the first power converter 84. FIG. 9(3) shows the PWM waveform to control the primary phase high triode for alternating current 528. Similarly bottom switches (primary phase high insulated gate bipolar transistor 144 and primary phase low insulated gate bipolar transistor 152 of the second power converter 84′) and the primary phase low triode for alternating current 536 can be switched using the primary phase voltage as a reference. These PWM waveforms may be generated using a PWM logic generation structure shown in FIG. 10 (shown for one phase of the multi-level converter 580). In more detail, an interlock time is utilized in operation between complementary converter switches, thus the blocks indicated as D are predetermined time delays based on a rising edge of the reference PWM signal. The gate_R node controls the primary phase high insulated gate bipolar transistor 144 and primary phase low insulated gate bipolar transistor 152 of the first power converter 84 and the primary phase high insulated gate bipolar transistor 144 and primary phase low insulated gate bipolar transistor 152 of the second power converter 84′. The gate_R_steer node controls to the primary phase high triode for alternating current 528 and the primary phase low triode for alternating current 536.

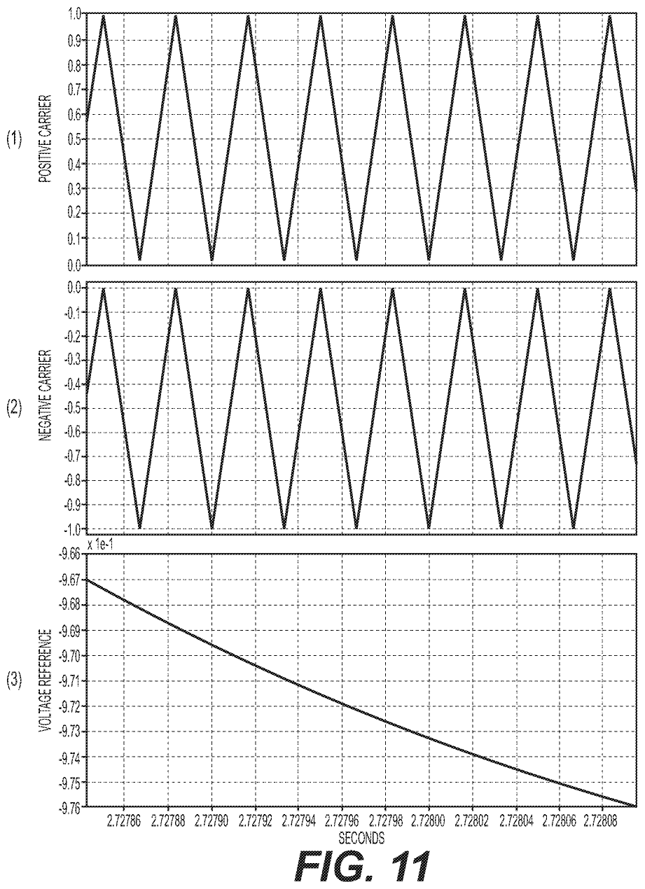

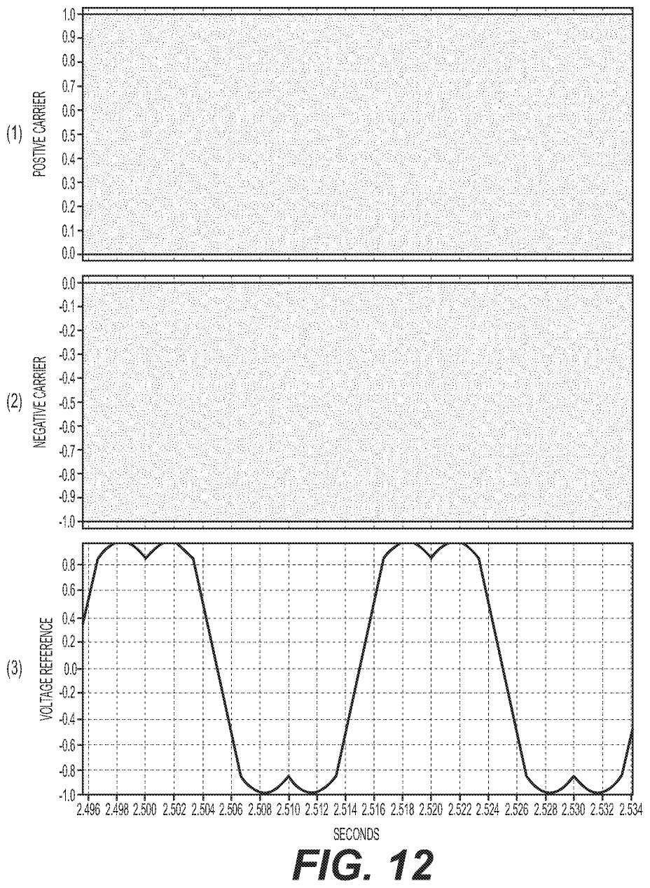

FIGS. 11(1)-11(3) show waveforms of positive and negative carrier signals (for input to the vc+ and vc− nodes of FIG. 10) with the corresponding reference voltage waveform (for input to the vr_ref node of FIG. 10). FIGS. 12(1)-12(3) show waveforms of positive and negative carrier signals (for input to the vc+ and vc− nodes in FIG. 10) with the corresponding reference voltage waveform (for input to the vr_ref node in FIG. 10).

In operation, the MOS gated TRIACs 527 or bi-directional IGBTs 227 are switched with reference voltages shown in FIGS. 9(1)-9(3). Again, the reference voltages are shown for only the top switches 144, 152 of the multilevel power converter 528. For the primary phase PWM switching allows both positive and negative current, while the pole voltage switches between +0.5Vdc and 0. The bottom MOS gated TRIAC (e.g., primary phase low triode for alternating current 536) or bi-directional IGBT 227 is closed during this time. In the negative half cycle of the primary phase reference voltage, complementarily bottom MOS gated TRIAC (primary phase high triode for alternating current 528) or bi-directional IGBT 227 is turned ON without stopping the output current. Again, this will allow both positive and negative current, while the pole voltage switches between 0 and −0.5Vdc. It is better to keep all the devices off while the corresponding MOS gated TRIAC 527 or bi-directional IGBT 227 is OFF.

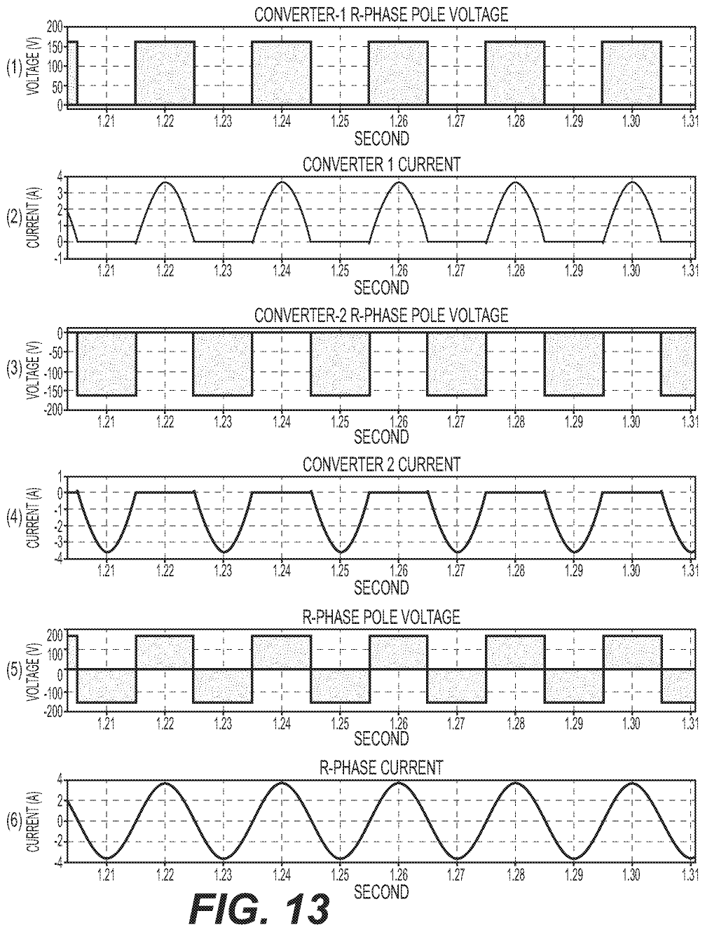

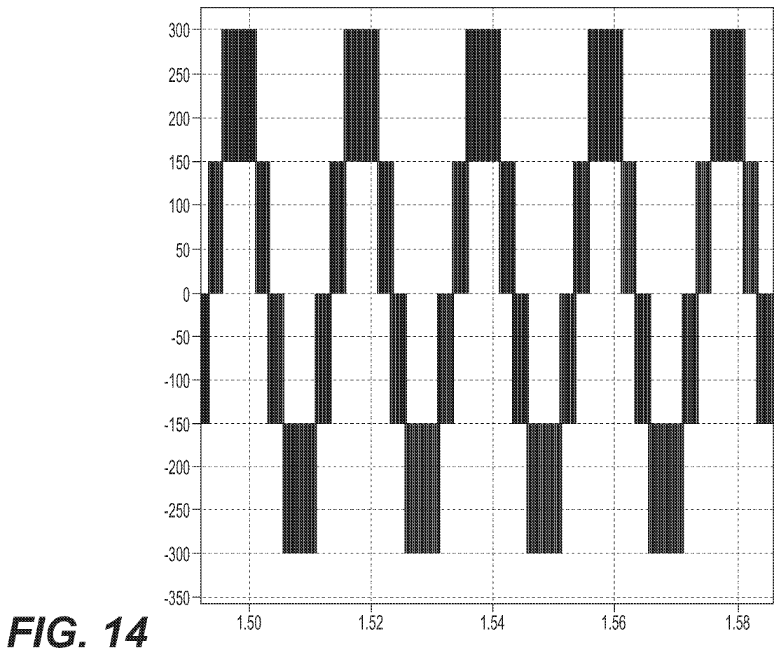

To illustrate the power rating of two converters 84, 84′, FIGS. 13(1)-13(6) show voltage and current waveforms for a 400V input voltage. Specifically, FIGS. 13(1) and 13(2) respectively show voltage and current waveforms at the first primary phase output line of the first power converter and FIGS. 13(3) and 13(4) respectively show voltage and current waveforms at the second primary phase output line of the second power converter. FIGS. 13(5) and 13(6) respectively show voltage and current waveforms at the primary phase final output line 210 (after the MOS gated TRIACs 527) during operation of the first power converter 84 and second power converter 84′. While, voltage and current waveforms are shown for a 400V input voltage, it should be appreciated that the motor drive circuit 500 including the scalable multilevel power converter 580 could be operated with an 800V input voltage.

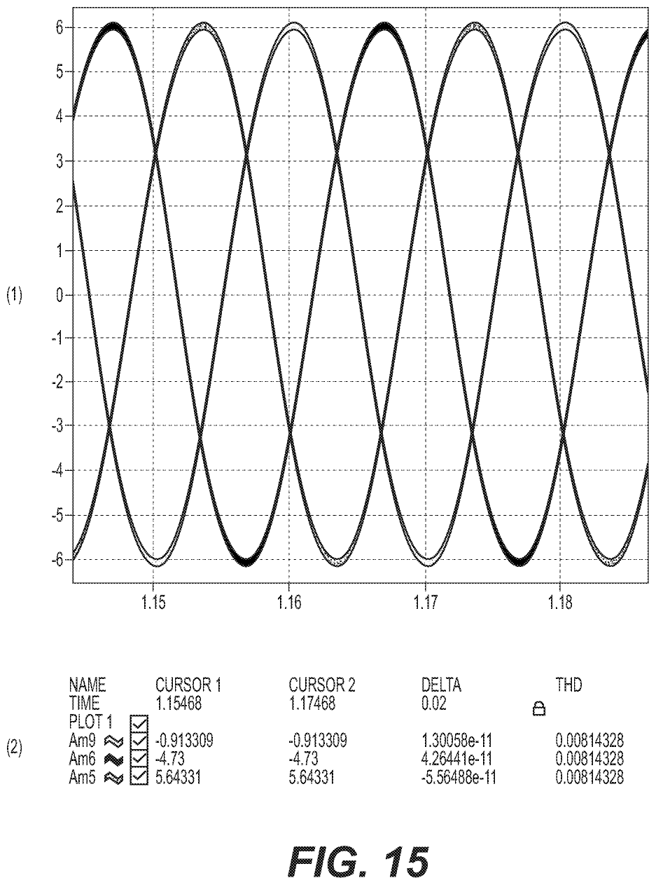

The neutral point clamped (NPC) three level converter 40 of U.S. Pat. No. 8,228,695 (shown in FIG. 3) suffers from becoming a two level converter through diodes 68 and 74 in a positive direction of current (i.e., current going out of the converter 40). In contrast, the bidirectional IGBTs 227 used as the bi-directional solid-state switches 227 in the examples shown in FIGS. 5A, 5B, 6A, 6B, 7A, and 7B and the metal oxide silicon controlled triode for alternating current (MOS gated TRIACs) used as the bi-directional solid-state switches 527 in the motor drive circuit 500 of FIG. 8 do not suffer such a deficiency. FIG. 15 shows an example line to line voltage of the motor drive circuit 500 shown in FIG. 8 (the resistive and inductive (RL) load used for the simulation included a resistance of 22 ohm and inductance of 3.5 millihenries).

Thus, the motor drive circuit 500 outputs the three phase current waveforms shown in FIG. 15(1). It should be noted that there is no high frequency noises other than switching frequency ripples in the waveforms output by the motor drive circuit 500. FIG. 15(2) illustrates FFT results of the three phase output current of the multilevel power converter 580 with switching frequency 30 kHz, interlock time 300 ns.

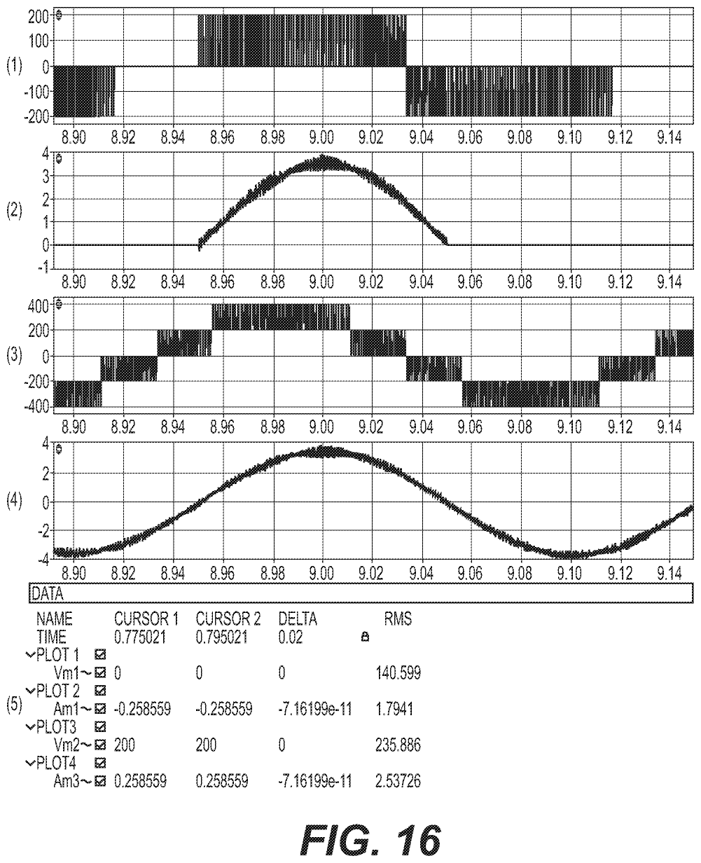

FIGS. 16(1)-16(5) illustrates the calculation of power for the two converters 84, 84′ of the multi-level converter 580. The voltage and current waveforms shown in FIGS. 16(1) and 16(2) are for the first power converter 84 and the voltage is a line to line voltage. The voltage and current waveforms in FIGS. 16(3) and 16(4) are what the motor drive circuit 500 outputs to the electric motor 32 during operation of the first power converter 84. FIG. 16(5) illustrates the specific values that may be utilized in calculating the power output of the motor drive circuit 500. The efficiency can be affected by the device drop of each of the MOS gated TRIACs 527 or bi-directional IGBTs 227. For example, the device drop of the each of the bi-directional IGBTs 227 with 200 amperes of current may be 2.3 volts (the IGBT and the diode in the path of current contributing 1.2+1.1 volts), while the device drop of each of the MOS gated TRIACs 527 may be 1.7 volts. Therefore, the conduction loss will be less for the scalable multilevel power converter 580 of FIG. 8 as compared to multilevel converters using bi-directional IGBTs 227.

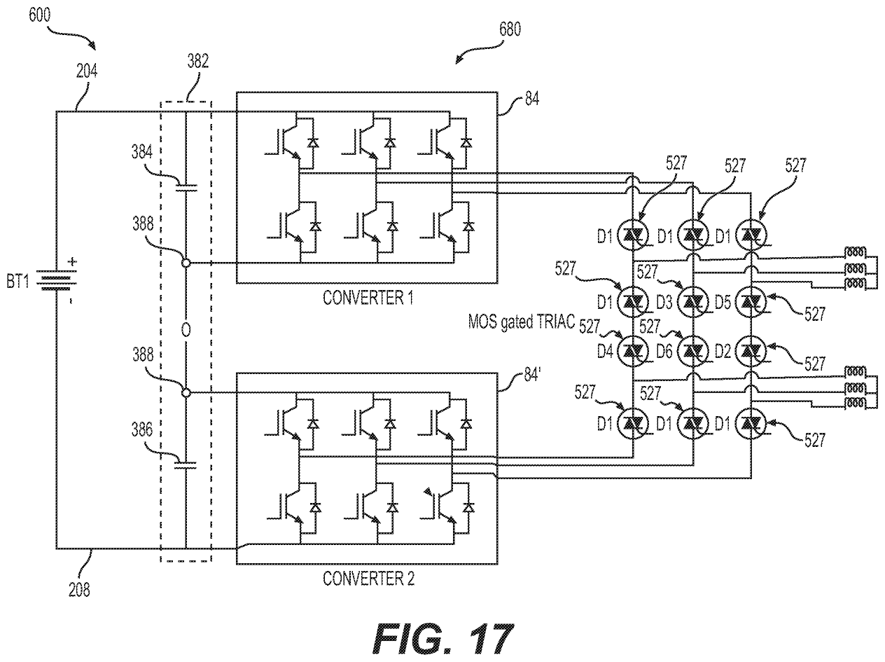

FIG. 17 shows another motor drive circuit 600 with MOS gated TRIACs as part of the scalable multilevel power converter 680. Specifically, two 2-level voltage source inverters (VSI) 84, 84′ can be used to work as the multilevel power converter 680 for each of a pair of three phase windings for different times of a drive cycle. Thus, there are twelve bi-directional solid-state switches 527 (MOS gated TRIACs). So, for example, during constant torque region, one set of winding can be used, and during other region, other set of winding can be used. In both cases, it is a three level converter.

This disclosure provides for scalability in voltage in multilevel power conversion as far as manufacturing of industrial grade multilevel power conversion is concerned. This concept of modularity with two-level converters 82, 82′, 84, 84′ as a basic building block, solves the problem of manufacturing and voltage imbalance complexity for higher level (N=5, 7 . . . ) multilevel power conversion, for example.

This disclosure provides an opportunity to have two separate circuit board based three-level converters with devices having a 650V rating, for example. So, a 3-level equivalent high-power converter (e.g., multilevel power converter 80, 280, 380, 480, 580, 680) can be built with two existing two-level converters 82, 82′, 84, 84′ (at half the power rating of the high-power converter. This will give a solution for an 800V battery system to run high voltage, high speed motors for EV applications. The disclosed multilevel power converter 80 using GaN switching transistors, for example, has reduced power conversion losses when compared to devices used in the prior art and can operate with a very low cost air cooled heatsink system.

Referring specifically to the motor drive circuit 500, other advantages include the three-level effect being provided by implementing the plurality of TRIAC switches 527. The cost of TRIAC switches 527 are comparable to silicon MOSFETs and available at higher voltages. Lower power level selection of the switches 527 can be realized, since the rating in each converter is lower than a conventional 2-level inverter and three legs of 3-level T-type neutral point clamped (TNPC). Such an arrangement requires half the voltage rating and the same current rating for each switch 527 in comparison to the high-power 2-level voltage source inverters 84, 84′. Thus, there is a reduced switching loss due to the lower voltage rating of the switches 527. In addition, each of the first power converter 84 and the second power converter 84′ is only conducting for half of a cycle. Therefore, the conduction loss is half in each of the converters 84, 84′. The thermal stress of the motor drive circuit (e.g., motor drive circuit 500) will be shared thereby halved on each converter 84, 84′. Low Voltage total harmonic distortion (THD) is also provided compared to conventional 2-level voltage source inverters. More specifically, the THD is comparable to a 3-level inverter. Less voltage ripple is caused by the inverter for the DC link when compared to 2-level inverter (comparable to 3-level inverter). A lower rate of change of voltage with respect to time (dV/dt) when compared to 2-level inverter is also provided (comparable to 3-level inverter). In addition, the disclosed motor drive circuit and multilevel power converters provide reduced EMI, E-drive losses, and NVH comparable to 3-level inverter. The disclosed motor drive circuit 500 is highly favorable for 800V powertrain applications, because two existing 400V 2-level inverters (the first power converter 84 and the second power converter 84′) can be used without changing the device specifications. If 400V battery is used, the devices 527 will see a maximum of only 200V across each. Finally, the per phase peak voltage is 1.39 times half the dc voltage for the disclosed motor drive circuit 500.

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom”, and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated degrees or at other orientations) and the spatially relative descriptions used herein interpreted accordingly.

1. A multilevel power converter for converting a direct current electrical power to an alternating current electrical power, comprising:
a plurality of converter inputs for receiving a direct current voltage of the direct current electrical power;
a primary phase final output line for outputting a primary phase output of the alternating current electrical power;
a secondary phase final output line for outputting a secondary phase output of the alternating current electrical power;
a tertiary phase final output line for outputting a tertiary phase output of the alternating current electrical power; and
a plurality of solid-state converter switches coupled to the plurality of converter inputs and to the primary phase final output line and the secondary phase final output line and the tertiary phase final output line and configured to switch the plurality of converter inputs to the primary phase final output line and the secondary phase final output line and the tertiary phase final output line, the plurality of solid-state converter switches comprise at least one 2-level converter including:
a positive direct current input line and a negative direct current input line coupled to the plurality of converter inputs,
a primary phase high transistor including one of a primary phase high drain and a primary phase high collector connected to the positive direct current input line, the primary phase high transistor including one of a primary phase high gate and a primary phase high base, the primary phase high transistor including one of a primary phase high source and a primary phase high emitter connected to a primary phase output line,
a primary phase low transistor including one of a primary phase low drain and a primary phase low collector connected to the one of the primary phase high source and the primary phase high emitter and the primary phase output line, the primary phase low transistor including one of a primary phase low gate and a primary phase low base, the primary phase low transistor including one of a primary phase low source and a primary phase low emitter connected to the negative direct current input line,
a secondary phase high transistor including one of a secondary phase high drain and a secondary phase high collector connected to the positive direct current input line, the secondary phase high transistor including one of a secondary phase high gate and a secondary phase high base, the secondary phase high transistor including one of a secondary phase high source and a secondary high emitter connected to a secondary phase output line,
a secondary phase low transistor including one of a secondary phase low drain and a secondary phase low collector connected to the secondary phase high source and the secondary phase output line, the secondary phase low transistor including one of a secondary phase low gate and a secondary phase low base, the secondary phase low transistor including one of a secondary phase low source and a secondary phase low emitter connected to the negative direct current input line;
a tertiary phase high transistor including one of a tertiary phase high drain and a tertiary phase high collector connected to the positive direct current input line, the tertiary phase high transistor including one of a tertiary phase high gate and a tertiary phase high base, the tertiary phase high transistor including one of a tertiary phase high source and a tertiary phase high emitter connected to a tertiary phase output line, and
a tertiary phase low transistor including one of a tertiary phase low drain and a tertiary phase low collector connected to the tertiary phase high source and the tertiary phase output line, the tertiary phase low transistor including one of a tertiary phase low gate and a tertiary phase low base, the tertiary phase low transistor including one of a tertiary phase low source and a tertiary phase low emitter connected to the negative direct current input line.

2. The multilevel power converter as set forth in claim 1, wherein each of the primary phase high transistor and the primary phase low transistor and the secondary phase high transistor and the secondary phase low transistor and the tertiary phase high transistor and the tertiary phase low transistor is a gallium nitride transistor.

3. The multilevel power converter as set forth in claim 1, wherein each of the primary phase high transistor and the primary phase low transistor and the secondary phase high transistor and the secondary phase low transistor and the tertiary phase high transistor and the tertiary phase low transistor is an insulated gate bipolar transistor.

4. The multilevel power converter as set forth in claim 1, wherein the plurality of converter inputs includes a 3-level positive direct current input line and a 3-level intermediate power input line and a 3-level negative direct current input line and the primary phase final output line is a 3-level primary phase output line and the secondary phase final output line is a 3-level secondary phase output line and the tertiary phase final output line is a 3-level tertiary phase output line and the plurality of solid state converter switches comprise at least one 2-level converter comprises:
a first 2-level converter configured to switch a first positive direct current input line coupled to the 3-level positive direct current input line and a first negative direct current input line coupled to the 3-level intermediate direct current input line to a first primary phase output line and a first secondary phase output line and a first tertiary phase output line, and
a second 2-level converter configured to switch a second positive direct current input line coupled to the 3-level positive direct current input line and a second negative direct current input line coupled to the 3-level negative direct current input line to a second primary phase output line and a second secondary phase output line and a second tertiary phase output line; and
the plurality of solid-state converter switches includes:
a 3-level output stage including a plurality of bi-directional solid-state switches configured to switch a corresponding one of the output lines from one of the first 2-level power converter and the second 2-level power converter to the 3-level primary phase output and the 3-level secondary phase output and the 3-level tertiary phase output.

5. A motor drive circuit for an electric motor, comprising:
a plurality of converter inputs for receiving a direct current voltage;
a first power converter including a plurality of solid-state converter switches configured to switch a plurality of first input lines coupled to at least one of the plurality of converter inputs to a first primary phase output line and a first secondary phase output line and a first tertiary phase output line for three AC phases of the electric motor;
a second power converter including a plurality of solid-state converter switches configured to switch a plurality of second input lines coupled to at least one of the plurality of converter inputs to a second primary phase output line and a second secondary phase output line and a second tertiary phase output line for the three AC phases of the electric motor; and
an output stage including a plurality of bi-directional solid-state switches configured to switch a corresponding one of the output lines from one of the first power converter and the second power converter to a primary phase final output line and a secondary phase final output line and a tertiary phase final output line to provide an AC power including the three AC phases to the electric motor.

6. The motor drive circuit as set forth in claim 5, wherein the plurality of converter inputs includes a 3-level positive direct current input line and a 3-level negative direct current input line;
the motor drive circuit further including a neutral-point clamped input stage coupled to the first power converter and the second power converter and including a first input capacitor and a second input capacitor connected in series across the 3-level positive direct current input line and the 3-level negative direct current input line having a DC voltage therebetween and including a midpoint terminal disposed between the first input capacitor and a second input capacitor and being energized to half of the DC voltage;
the first power converter being a first 2-level converter and the plurality of first input lines includes a first positive direct current input line coupled to the 3-level positive direct current input line and a first negative direct current input line coupled to the midpoint terminal, the first 2-level converter configured to switch the first positive direct current input line and the first negative direct current input line to the first primary phase output line and the first secondary phase output line and the first tertiary phase output line; and
the second power converter being a second 2-level converter and plurality of second input lines includes a second positive direct current input line coupled to the midpoint terminal and a second negative direct current input line coupled to the 3-level negative direct current input line, the second 2-level converter configured to switch the second positive direct current input line and the second negative direct current input line to the second primary phase output line and the second secondary phase output line and the second tertiary phase output line.

7. The motor drive circuit as set forth in claim 5, wherein the plurality of converter inputs includes a 5-level positive direct current input line and a 5-level first intermediate direct current input line and a 5-level second intermediate direct current input line and a 5-level third intermediate direct current input line and a 5-level negative direct current input line and each of the first power converter and the second power converter is a 3-level converter comprising:
a 3-level positive direct current input line coupled to one of the 5-level positive direct current input line and the 5-level second intermediate direct current input line and a 3-level intermediate direct current input line coupled to one of the 5-level first intermediate direct current input line and the 5-level third direct current input line and a 3-level negative direct current input line coupled to one of the 5-level second intermediate direct current input line and the 5-level negative direct current input line;
a first 2-level converter configured to switch a first positive direct current input line coupled to the 3-level positive direct current input line and a first negative direct current input line coupled to the 3-level intermediate direct current input line to a first primary phase output line and a first secondary phase output line and a first tertiary phase output line;
a second 2-level converter configured to switch a second positive direct current input line coupled to the 3-level intermediate direct current input line and a second negative direct current input line coupled to the 3-level negative direct current input line to the second primary phase output line and the second secondary phase output line and the second tertiary phase output line; and
a 3-level output stage including a plurality of 3-level bi-directional solid-state switches configured to switch a corresponding one of the output lines from one of the first 2-level power converter and the second 2-level power converter to a 3-level primary phase output line and a 3-level secondary phase output line and a 3-level tertiary phase output line.

8. The motor drive circuit as set forth in claim 5, wherein each of the plurality of solid-state converter switches is a gallium nitride (GaN) transistor.

9. The motor drive circuit as set forth in claim 8, wherein the plurality of solid-state converter switches includes:
a primary phase high gallium nitride transistor including a primary phase high drain connected to the positive direct current input line and a primary phase high gate and a primary phase high source connected to the primary phase output line;
a primary phase low gallium nitride transistor including a primary phase low drain connected to the primary phase high source and the primary phase output line and a primary phase low gate and a primary phase low source connected to the negative direct current input line;
a secondary phase high gallium nitride transistor including a secondary phase high drain connected to the positive direct current input line and a secondary phase high gate and a secondary phase high source connected to the secondary phase output line;
a secondary phase low gallium nitride transistor including a secondary phase low drain connected to the secondary phase high source and the secondary phase output line and a secondary phase low gate and a secondary phase low source connected to the negative direct current input line;
a tertiary phase high gallium nitride transistor including a tertiary phase high drain connected to the positive direct current input line and a tertiary phase high gate and a tertiary phase high source connected to the tertiary phase output line; and
a tertiary phase low gallium nitride transistor including a tertiary phase low drain connected to the tertiary phase high source and the tertiary phase output line and a tertiary phase low gate and a tertiary phase low source connected to the negative direct current input line.

10. The motor drive circuit as set forth in claim 5, wherein each of the plurality of solid-state converter switches is an insulated gate bipolar transistor.

11. The motor drive circuit as set forth in claim 10, wherein the plurality of solid-state converter switches includes:
a primary phase high insulated gate bipolar transistor including a primary phase high collector connected to the positive direct current input line and a primary phase high base and a primary phase high emitter connected to the primary phase output line;
a primary phase low insulated gate bipolar transistor including a primary phase low collector connected to the primary phase high emitter and the primary phase output line and a primary phase low base and a primary phase low emitter connected to the negative direct current input line;
a secondary phase high insulated gate bipolar transistor including a secondary phase high collector connected to the positive direct current input line and a secondary phase high base and a secondary phase high emitter connected to the secondary phase output line;
a secondary phase low insulated gate bipolar transistor including a secondary phase low collector connected to the secondary phase high emitter and the secondary phase output line and a secondary phase low base and a secondary phase low emitter connected to the negative direct current input line;
a tertiary phase high insulated gate bipolar transistor including a tertiary phase high collector connected to the positive direct current input line and a tertiary phase high base and a tertiary phase high emitter connected to the tertiary phase output line; and
a tertiary phase low insulated gate bipolar transistor including a tertiary phase low collector connected to the tertiary phase high emitter and the tertiary phase output line and a tertiary phase low base and a tertiary phase low emitter connected to the negative direct current input line.

12. The motor drive circuit as set forth in claim 5, wherein each of the plurality of bi-directional solid-state switches is an insulated gate bipolar transistor.

13. The motor drive circuit as set forth in claim 12, wherein the plurality of bi-directional solid-state switches includes:
a first primary phase upper insulated gate bipolar transistor including a first primary phase upper drain coupled to the first primary phase output line of the first power converter and a first primary phase upper gate and a first primary phase upper source;
a second primary phase upper insulated gate bipolar transistor including a second primary phase upper drain coupled to the primary phase final output line and a second primary phase upper gate and a second primary phase upper source coupled to the first primary phase upper source;
a first primary phase lower insulated gate bipolar transistor including a first primary phase lower drain coupled to the primary phase final output line and a first primary phase lower gate and a first primary phase lower source;
a second primary phase lower insulated gate bipolar transistor including a second primary phase lower drain coupled to the second primary phase output line of the second power converter and a second primary phase lower gate and a second primary phase lower source coupled to the first primary phase lower source;
a first secondary phase upper insulated gate bipolar transistor including a first secondary phase upper drain coupled to the first secondary phase output line of the first power converter and a first secondary phase upper gate and a first secondary phase upper source;
a second secondary phase upper insulated gate bipolar transistor including a second secondary phase upper drain coupled to the secondary phase final output line and a second secondary phase upper gate and a second secondary phase upper source coupled to the first secondary phase upper source;
a first secondary phase lower insulated gate bipolar transistor including a first secondary phase lower drain coupled to the secondary phase final output line and a first secondary phase lower gate and a first secondary phase lower source;
a second secondary phase lower insulated gate bipolar transistor including a second secondary phase lower drain coupled to the second secondary phase output line of the second power converter and a second secondary phase lower gate and a second secondary phase lower source coupled to the first secondary phase lower source;
a first tertiary phase upper insulated gate bipolar transistor including a first tertiary phase upper drain coupled to the first tertiary phase output line of the first power converter and a first tertiary phase upper gate and a first tertiary phase upper source;
a second tertiary phase upper insulated gate bipolar transistor including a second tertiary phase upper drain coupled to the tertiary phase final output line and a second tertiary phase upper gate and a second tertiary phase upper source coupled to the first tertiary phase upper source;
a first tertiary phase lower insulated gate bipolar transistor including a first tertiary phase lower drain coupled to the secondary phase final output line and a first tertiary phase lower gate and a first tertiary phase lower source; and
a second tertiary phase lower insulated gate bipolar transistor including a second tertiary phase lower drain coupled to the second tertiary phase output line of the second power converter and a second tertiary phase lower gate and a second tertiary phase lower source coupled to the first tertiary phase lower source.

14. The motor drive circuit as set forth in claim 5, wherein each of the plurality of bi-directional solid-state switches is a metal oxide silicon controlled triode for alternating current.

15. The motor drive circuit as set forth in claim 14, wherein the plurality of bi-directional solid-state switches includes:
a primary phase high triode for alternating current including a primary phase high triode first anode coupled to the primary phase final output line and a primary phase high triode gate and a primary phase high triode second anode coupled to the first primary phase output line of the first power converter;
a primary phase low triode for alternating current including a primary phase low triode first anode coupled to the second primary phase output line of the second power converter and a primary phase low triode gate and a primary phase low triode second anode coupled to the primary phase high triode first anode and the primary phase final output line;
a secondary phase high triode for alternating current including a secondary phase high triode first anode coupled to the secondary phase final output line and a secondary phase high triode gate and a secondary phase high triode second anode coupled to the first secondary phase output line of the first power converter;
a secondary phase low triode for alternating current including a secondary phase low triode first anode coupled to the second secondary phase output line of the second power converter and a secondary phase low triode gate and a secondary phase low triode second anode coupled to the secondary phase high triode first anode and the secondary phase final output line;
a tertiary phase high triode for alternating current including a tertiary phase high triode first anode coupled to the tertiary phase final output line and a tertiary phase high triode gate and a tertiary phase high triode second anode coupled to the first tertiary phase output line of the first power converter; and
a tertiary phase low triode for alternating current including a tertiary phase low triode first anode coupled to the second tertiary phase output line of the second power converter and a tertiary phase low triode gate and a tertiary phase low triode second anode coupled to the tertiary phase high triode first anode and the tertiary phase final output line.

16. The multilevel power converter as set forth in claim 1, wherein the plurality of converter inputs includes a 5-level positive direct current input line and a 5-level first intermediate direct current input line and a 5-level second intermediate direct current input line and a 5-level third intermediate direct current input line and a 5-level negative direct current input line and the primary phase final output line is a 5-level primary phase final output line and the secondary phase final output line is a 5-level secondary phase final output line and the tertiary phase final output line is a 5-level tertiary phase final output line and the at least one 2-level converter includes a plurality of 2-level converters comprising a plurality of 3-level converters each including:
a 3-level positive direct current input line coupled to one of the 5-level positive direct current input line and the 5-level second intermediate direct current input line and a 3-level intermediate direct current input line coupled to one of the 5-level first intermediate direct current input line and the 5-level third direct current input line and a 3-level negative direct current input line coupled to one of the 5-level second intermediate direct current input line and the 5-level negative direct current input line;
a first 2-level converter configured to switch a first positive direct current input line coupled to the 3-level positive direct current input line and a first negative direct current input line coupled to the 3-level intermediate direct current input line to a first primary phase output line and a first secondary phase output line and a first tertiary phase output line;
a second 2-level converter configured to switch a second positive direct current input line coupled to the 3-level intermediate direct current input line and a second negative direct current input line coupled to the 3-level negative direct current input line to the second primary phase output line and the second secondary phase output line and the second tertiary phase output line; and
a 3-level output stage including a plurality of 3-level bi-directional solid-state switches configured to switch a corresponding one of the output lines from one of the first 2-level power converter and the second 2-level power converter to a 3-level primary phase output line and a 3-level secondary phase output line and a 3-level tertiary phase output line.

17. The multilevel power converter as set forth in claim 16, further including a 5-level output stage including a plurality of bi-directional solid-state switches configured to switch a corresponding one of the 3-level primary phase output line and the 3-level secondary phase output line and the 3-level tertiary phase output line from each of the plurality of 3-level converters to the 5-level primary phase final output line and the 5-level secondary phase final output line and the 5-level tertiary phase final output line.

18. The multilevel power converter as set forth in claim 17, wherein each of the plurality of bi-directional solid-state switches is an insulated gate bipolar transistor.

19. The motor drive circuit as set forth in claim 7, further including a 5-level output stage including a plurality of bi-directional solid-state switches configured to switch a corresponding one of the 3-level primary phase output line and the 3-level secondary phase output line and the 3-level tertiary phase output line from each of the first power converter and the second power converter to the 5-level primary phase final output line and the 5-level secondary phase final output line and the 5-level tertiary phase final output line.

20. The motor drive circuit as set forth in claim 19, wherein each of the plurality of bi-directional solid-state switches is an insulated gate bipolar transistor.
